(19) United States
(12) Patent Application Publication
(10) Pub. No.: US 2014/0210503 A1
(43) Pub. Date: Jul. 31, 2014

(54) STARTUP BOOT CYCLE TESTING OF A MOBILE DEVICE AT DIMINISHED POWER SUPPLY CURRENT

(71) Applicant: Apple Inc., Cupertino, CA (US)

(72) Inventor: Ching-Yu John Tam, Los Gatos, CA (US)

(73) Assignee: Apple Inc., Cupertino, CA (US)

(21) Appl. No.: 13/972,734

(22) Filed: Aug. 21, 2013

Related U.S. Application Data
(60) Provisional application No. 61/696,039, filed on Aug. 31, 2012.

(51) Int. Cl. G01R 19/00

(52) U.S. Cl. CPC G01R 19/0092
USPC 324/754.03; 324/537

(57) ABSTRACT

A startup boot cycle test system for testing a mobile multi-function device under test (DUT) that has a power manager and a main system processor is described. The system includes an external power source and a tester device. The external power source provides an input current to the power manager, which in turn provides a boot current, drawn from the input current, to the main system processor. The tester device connects to a test point in the DUT using a contact test probe to draw a margin current from the boot current. The resulting diminished boot current is used by the processor to boot. The tester device detects whether the processor successfully boots using the diminished boot current using a data input connector connected between the DUT and tester device. Other embodiments are also described and claimed.

### RELATED MATTERS

This application claims the benefit of the earlier filing date of provisional application No. 61/696,039, filed Aug. 31, 2012.

### FIELD

An embodiment relates to a tester device that steals a margin current from a main system processor of a mobile multi-function device to test whether the main system processor can boot using a diminished current. Other embodiments are also described.

### BACKGROUND

Mobile multi-function devices include a main system processor that runs the operating system and performs the basic arithmetical, logical, and input/ output operations of the mobile device. Generally mobile devices are powered by an integrated battery, but are sometimes capable of being powered by external power sources. In some situations the battery may be depleted (e.g. zero charge or low charge) and cannot power the device during startup boot procedures. In these situations, the mobile device must rely on an external source to power the mobile device during boot procedures.

While performing boot procedures, a current limiter in the mobile device restricts the flow of current to the device from an external source. This current limit is raised after the mobile device has successfully booted. Manufactures often set this current limit as low as possible while booting to ensure the draw of current by the mobile device does not damage or negatively affect the external power source or the mobile device. Since this current limit is low and at the edge of what is necessary to boot the mobile device, manufacturers seek to test the ability of their processors to boot using these lower current levels.

### SUMMARY

There is a need for a system and method for testing the tolerance of the default low current startup condition of a mobile multi-function device. By stealing current provided by an external power source, less power is available to startup the device. The amount of current stolen that stills allows the main system of the device to startup is the power margin available.

An embodiment relates to a startup boot cycle test system for testing a mobile multi-function device under test (DUT) that has a power manager and a main system processor. The system includes an external power source and a tester device. The external power source provides an input current to the power manager. The power manager has an integrated current limiter that limits the amount of current drawn by the DUT from the external power source during boot/ startup and provides power to the main system and charging circuits of the DUT. The tester device connects to a test point in the DUT using a contact test probe to steal current from the boot current provided to the main system of the DUT. The resulting diminished boot current is used by the system to boot. The tester device detects whether the processor successfully boots using the diminished boot current using a data input connector connected between the DUT and the tester device. In another embodiment, the processor may itself determine it has successfully booted using the diminished boot current and report the results to the tester device or directly to a test engineer. By drawing the margin current, the tester device determines whether the processor can boot solely using a low/diminished current that falls below the current level set by a current limiter in the DUT. If the processor is able to boot using this diminished current, the processor will likely boot using the higher current set by the current limiter during normal operation of the DUT.

The above summary does not include an exhaustive list of all aspects of the present invention. It is contemplated that the invention includes all systems and methods that can be practiced from all suitable combinations of the various aspects summarized above, as well as those disclosed in the Detailed Description below and particularly pointed out in the claims filed with the application. Such combinations have particular advantages not specifically recited in the above summary.

### BRIEF DESCRIPTION OF THE DRAWINGS

The embodiments of the invention are illustrated by way of example and not by way of limitation in the figures of the accompanying drawings in which like references indicate similar elements. It should be noted that references to “an” or “ one” embodiment of the invention in this disclosure are not necessarily to the same embodiment, and they mean at least one.

FIG. 1 shows a human user holding different types of mobile multi-function communications devices, namely a smart phone and a tablet-like personal computer.

FIGS. 2A and 2B show functional unit block diagrams and some constituent hardware components of a startup boot cycle test systems for testing the mobile multi-function communications devices with a tester device.

FIG. 3 shows a partial diagram of display driver circuitry of a mobile multi-function communications device with a test point as arranged in FIG. 2B.

FIG. 4 shows a functional unit block diagram and some constituent hardware components of the tester device.

FIG. 5 shows a method for testing the tolerance of a processor in a mobile multi-function communications device according to one embodiment.

### DETAILED DESCRIPTION

Several embodiments are described with reference to the appended drawings are now explained. While numerous details are set forth, it is understood that some embodiments of the invention may be practiced without these details. In other instances, well-known circuits, structures, and techniques have not been shown in detail so as not to obscure the understanding of this description.

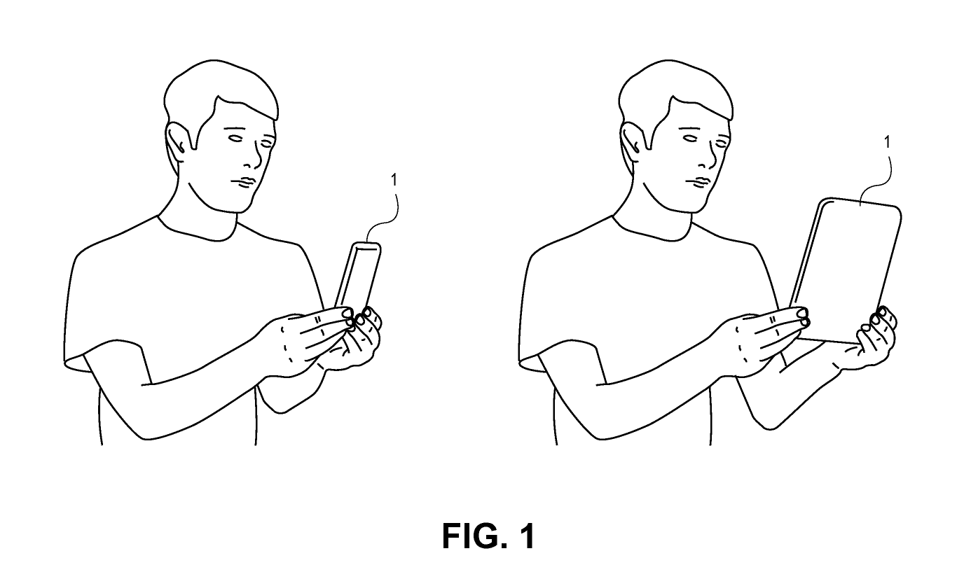

FIG. 1 shows two instances of a mobile multi-function communications device under test (DUT) 1 held in the hands of an end user (owner) of the device 1. The multi-function mobile communications DUT 1 may also be referred to here as a mobile communications DUT, a mobile DUT, or a DUT. In one instance, the DUT 1 is a smart phone or a cellular phone with several features typically available in modern wireless communication devices, such as a touch screen interface, music, video file recording, video file playback, digital camera, and wireless-enabled applications such as voice over internet protocol telephony, electronic calendar, web browser, and email. For example, the DUT 1 may be an iPhone™device by Apple Inc. In another instance, the DUT 1 may be a larger computer such as a tablet computer or a notebook/ netbook computer. For example, the DUT 1 may be an iPad™device by Apple Inc.

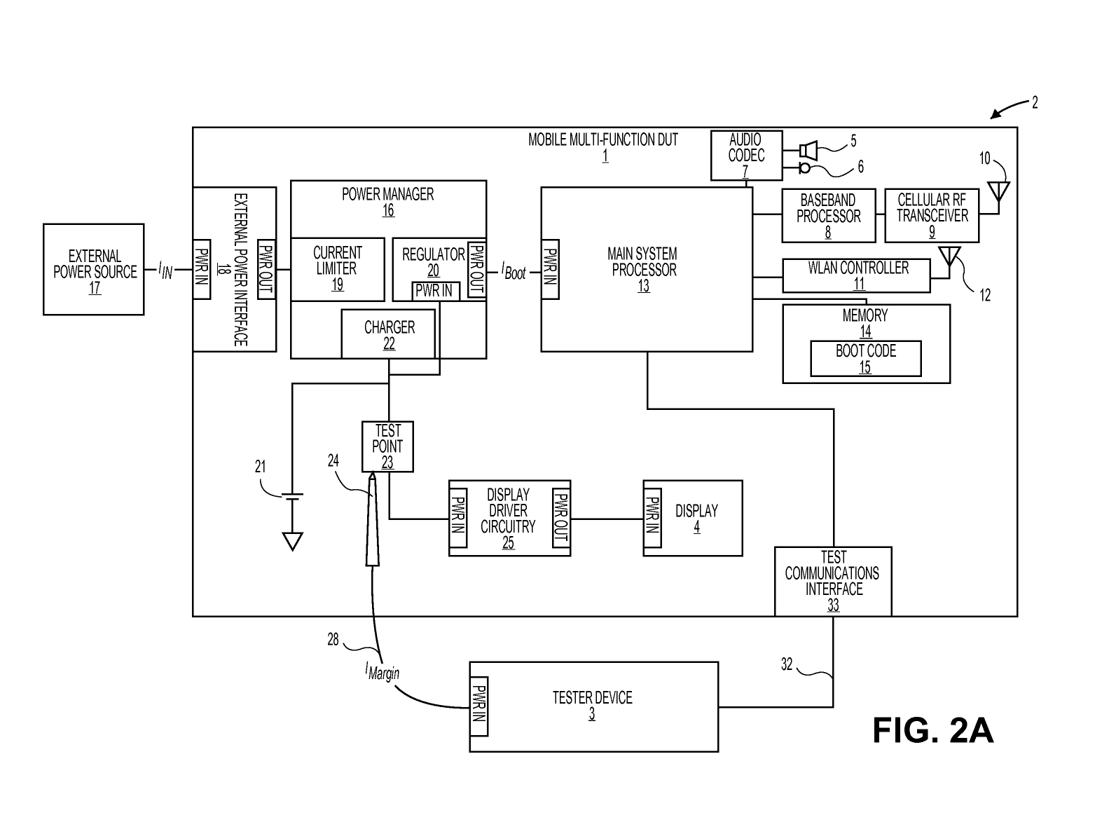

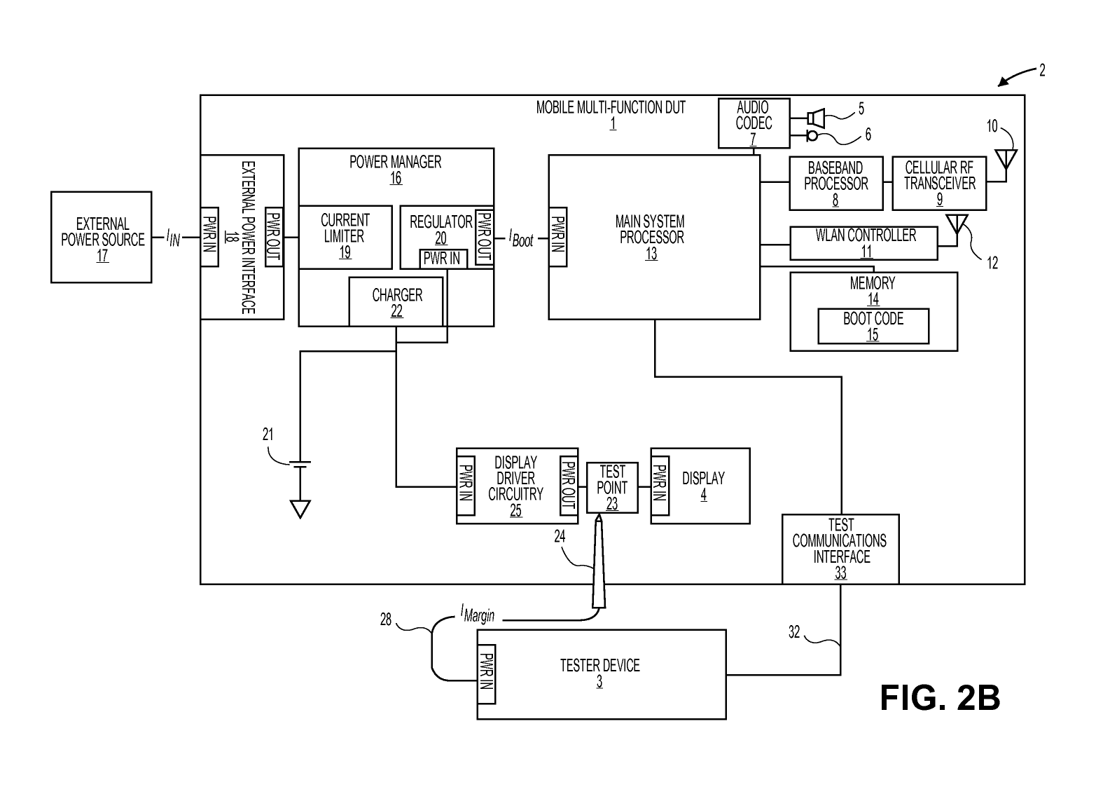

FIGS. 2A and 2B show functional unit block diagrams and some constituent hardware components of a boot cycle test system 2 for testing the mobile DUT 1 with a tester device 3. As will be described in further detail below, the tester device 3 tests the ability of the DUT 1 to boot using a relatively low or diminished boot current that falls below an already low current level set by a current limiter in the DUT 1.

Although not shown, the DUT 1 has a housing in which the primary mechanism for visual and tactile interaction with its user is a touch sensitive display screen 4. The housing may be essentially a solid volume referred to as candy bar or chocolate bar type as in the iPhone™device. An alternative is one that has a moveable, multi-piece housing, such as a clamshell design, or one with a sliding, physical keypad as used by other cellular and mobile handset or smart phone manufacturers. The touch display screen 4 is used to display typical features of visual voicemail, web browser, email, and digital camera viewfinder, as well as others, and to receive input from the user via virtual buttons and touch commands.

For wireless telephony, which enables the user to receive and place audio and/or video calls, downlink audio during a call can be emitted from a speaker 5 (which may be an earpiece speaker or receiver, or it may be a headset earphone). Uplink audio includes the user's speech, which is picked up by a microphone 6 (e.g., mouthpiece microphone or headset microphone). Conversion between analog domain and digital domain for the speaker and microphone signals, in addition to digital audio signal processing for different applications running in the DUT 1, may be performed within audio codec 7. The codec 7 may be configured to operate in different modes, e.g. to service a digital media player function (such as an MP3 player that is playing back a music file that is stored in the DUT 1), as well as a wireless telephony function.

For wireless telephony, a baseband processor 8 is included to perform speech coding and decoding functions upon the uplink and downlink signals, respectively, in accordance with the specifications of a given protocol (e.g., cellular GSM, cellular CDMA, wireless VOIP). A cellular RF transceiver 9 receives the coded uplink signal from the baseband processor 8 and up converts it to a carrier band before driving an antenna 10 with it; it receives a downlink signal from the antenna 10 and down converts the signal to baseband before passing it to the baseband processor 8. A wireless local area network (WLAN) controller 11 receives and transmits data packets from a nearby wireless router or access point, using an antenna 12.

The basic boot operations and user-level functions of the DUT 1 are implemented under control of a main system processor 13 that has been programmed in accordance with instructions (code and data) stored in memory 14. The processor 13 and memory 14 are generically used here to refer to any suitable combination of programmable data processing components and data storage that conduct the operations needed to implement the various functions and operations of the DUT 1. The processor 13 may be an applications processor typically found in a smart phone, while the memory 14 may refer to microelectronic, non-volatile random access memory. An operating system may be stored in the memory 14, along with application programs specific to the various functions of the DUT 1, which are to be run or executed by the processor 13 to perform the various functions of the DUT 1. For instance, there may be a telephony application that (when launched, unsuspended, or brought to foreground) enables the user to “dial” a telephone number to initiate a telephone call using a wireless VOIP or a cellular protocol and to “hang up” on the call when finished.

In one embodiment, the memory 14 stores boot code 15 that may be run by the processor 13 for booting the DUT 1. As used herein, booting involves the complete powering on of the DUT 1 from a completely powered off state. The boot code 15 may include data and code for performing power-on reset (POR) operations, power-on self-test (POST) operations, operations for finding, loading and starting an operating system, and operations for enumerating the DUT 1 with a host device.

The DUT 1 may include a power management unit (PMU) 16 integrated in the housing of the DUT 1. The PMU 16 may be implemented as a programmed processor, with associated analog and digital conversion circuitry, analog signal conditioning circuitry, and a data communications interface needed to control or communicate with other components of the DUT 1. The PMU 16 may receive an input current/in from an external power source 17 through an external power interface 18 (e.g., a multi-pin docking connector) that is integrated in the housing of the DUT 1. The external power source 17 may be any device for providing an input current Iᵢₙ to the DUT 1 such that the DUT 1 may perform the boot code 15 stored in the memory 14 and thereafter perform general computing operations.

The PMU 16 may include a current limiter 19 for imposing a preset upper current limit to the amount of current drawn from the external power source 17 by the DUT 1. For example, an external power source 17, such as a USB host device, may be capable of providing 500 mA to the PMU 16 through the external power interface 18, but the current limiter 19 restricts/ limits the draw by the PMU 16 to a current limit of 100 mA. This preset current limit may be needed to comply with a functional specification, such as the USB 2.0 standard, and/ or to protect components of the DUT 1. The current limit may be stored in volatile memory in the DUT 1 and may be set during manufacture of the DUT 1. In one embodiment, the current limiter 19 may change current limits based on the state of the DUT 1. For example, while the DUT 1 is booting, the current limit may be set at 100 mA. Upon successfully booting the DUT 1, the current limit may be increased to 500 mA.

The PMU 16 may include a voltage regulator 20 for maintaining a constant voltage level to the main system processor 13. For example, if a voltage delivered to the processor 13 is too low the voltage regulator 20 may produce a higher voltage level. If the voltage delivered to the processor 13 is too high, the voltage regulator 20 may produce a lower voltage. The voltage regulator 20 may be any device for regulating voltage delivered to the processor 13. For example, the voltage regulator 20 may be defined by a low dropout regulator or a buck regulator. The voltage regulator 20 provides a boot current I_{boot} to the processor 13 and other components needed to boot the DUT 1 from the input current Iᵢₙ. The boot current I_{boot} is the only available current provided to the processor 13 during boot operations.

In one embodiment, the DUT 1 may include a battery 21 that under normal operating conditions is the main power source for the DUT 1, including the processor 13. The battery 21 may be charged or replenished by the external power source 17 such as a universal serial bus (USB) host, a wall plug, or automobile battery dc power adapter that connect to the external power interface 18 (e.g., a multi-pin docking connector) that is also integrated in the housing of the DUT 1. Charging operations may be controlled by a charger 22 that is integrated within the PMU 16. The charger 22 controls the flow of current to the battery 21 from the external power source 17 such that the battery 21 may be charged.

When the battery 21 has a low charge and cannot boot the DUT 1, the external power source 17 may be needed to directly power the processor 13. For example, power from an external power source 17 may be needed to boot the DUT 1 such that the DUT 1 can begin to charge a dead battery 21. Accordingly, the external power source 17 may need to power the processor 13 during all boot operations without assistance from the battery 21.

Mobile devices, including the DUT 1, vary in the level of current (Iᵢₙ) they are allowed to draw from external power sources 17 based on various standards. For example, the USB 2.0 standard allows a client device (e.g., the DUT 1) to draw only 100 mA from a host device (e.g., the external power source 17) while the client is booting. This current limit may be enforced by the current limiter 19 in the DUT 1. The input current Iᵢₙ is used to provide the boot current I_{boot} to the DUT 1, including the processor 13, for performing boot operations. To ensure the processor 13 in the DUT 1 is capable of booting using a current restricted by the current limiter 19, the tester device 3 steals a margin current I_{margin} from the boot current I_{boot} to produce a diminished boot current. If the DUT 1 is able to boot using the diminished boot current that is lower than the current level restricted by the current limiter 19, the DUT 1 is likely to boot under normal conditions using the current level restricted by only the current limiter 19. The margin current I_{margin} defines the power margin available below the current limit set by the current limiter 19 that allows the DUT 1 to boot.

The diminished boot current created by the tester device 3 is equal to the difference between the boot current I_{boot} and the margin current I_{margin}(i.e., I_{boot}−I_{margin}). For example, if the current limiter 19 in conjunction with the voltage regulator 20 outputs a boot current I_{boot} of 100 mA to power the DUT 1 during boot operations and the margin current I_{margin} in is set to 25 mA, the diminished boot current is 75 mA. The processor 13 uses this diminished boot current to perform all boot operations. If the tester device 3 detects a successful boot using the diminished boot current, the manufacture or testing group can be reasonably assured that the processor 13 will boot using the higher current level set by the current limiter 19 during normal operation of the DUT 1.

The margin current I_{margin} may be preset during construction of the tester device 3 or the margin current I_{margin} may be set during testing by a test engineer. In one embodiment, the tester device 3 may include an input device (e.g., a set of buttons, knobs, keys, or touch sensitive display) for receiving an input from a test engineer that sets the margin current I_{margin}. In other embodiments, the margin current I_{margin} may be set by a remote device through a wired or wireless connection to the tester device 3.

As shown in FIGS. 2A and 2B, the tester device 3 may be coupled to a test point 23 in the DUT 1 to draw the margin current I_{margin} using a contact test probe 24. In one embodiment, the contact test probe 24 accesses the test point 23 after a housing of the DUT 1 has been removed and the circuitry of the DUT 1 has been exposed. The test point 23 may be located within an electronic circuit of the DUT 1 that provides the tester device 3 access to the boot current I_{boot}. The test point 23 may include pins for attachment of the contact test probe 24. In one embodiment, the test point 23 is a tinned solder pad that is added to the DUT 1 during manufacturing. The test point 23 may be used for drawing a current (e.g., margin current I_{margin}), monitoring the state of the DUT 1, or for injecting test signals.

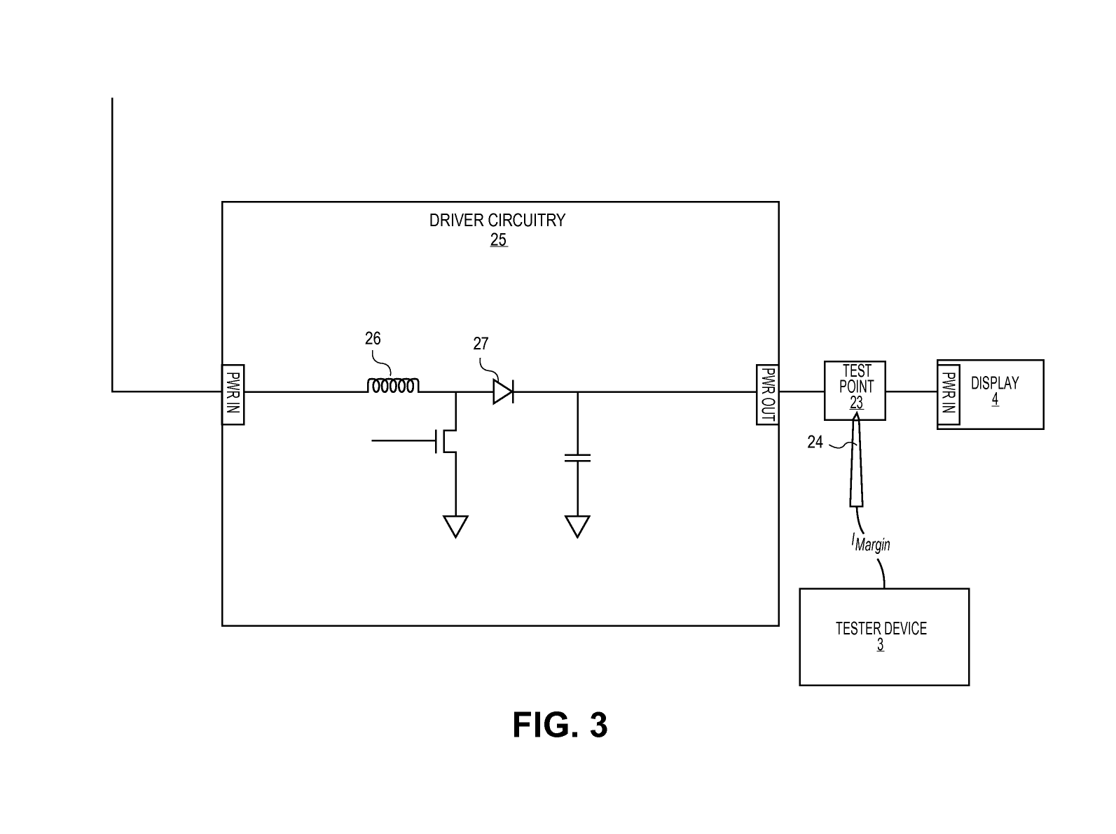

The test point 23 may be located at various locations within the circuitry of the DUT 1. As shown in FIG. 2A, the test point 23 is located on a power supply circuit trace that connects the PMU 16 to a power supply input of display driver circuitry 25 that is used for controlling the touch display panel 4. As shown in FIG. 2B, the test point 23 is located on a power supply circuit trace that connects the display driver circuitry 25 to the touch display panel 4 of the DUT 1. FIG. 3 shows a partial diagram of the display driver circuitry 25 and the test point 23 as arranged in FIG. 2B. The display driver circuitry 25 includes an inductor 26 in series with a diode 27. By locating the test point 23 on a circuit trace in series with the inductor 26 and the diode 27, the tester device 3 can draw the margin current I_{margin} from the boot current I_{boot} when the touch display panel 4 is not activated. Since the touch display panel 4 does not need to be activated or turned on, the process of testing the DUT 1 is simplified by not needing to take into account the current draw of the touch display panel 4.

Although shown as being located proximate to the PMU 16, the display driver circuitry 25, and the touch display panel 4, the test point 23 may be located in other locations in the DUT 1 that allow the margin current I_{margin} to be drawn from the boot current I_{boot}. The test point 23 may be pre-existing or may be specifically added during manufacture of the DUT 1 for the exclusive purpose of drawing the margin current I_{margin}.

As noted above, the tester device 3 includes a contact test probe 24 for contacting the test point 23 and stealing the margin current I_{margin} from the boot current I_{boot}. The contact test probe 24 is an electrically conductive lead that is coupled to the tester device 3 with a wire 28. The contact test probe 24 may include a clip or coupling device for attaching to the test point 23. For example, the contact test probe 24 may include tweezers for coupling to a pin of the test point 23. In one embodiment, the tester device 3 may include multiple contact test probes 24 for coupling to various test points 23 in the same or different DUTs 1.

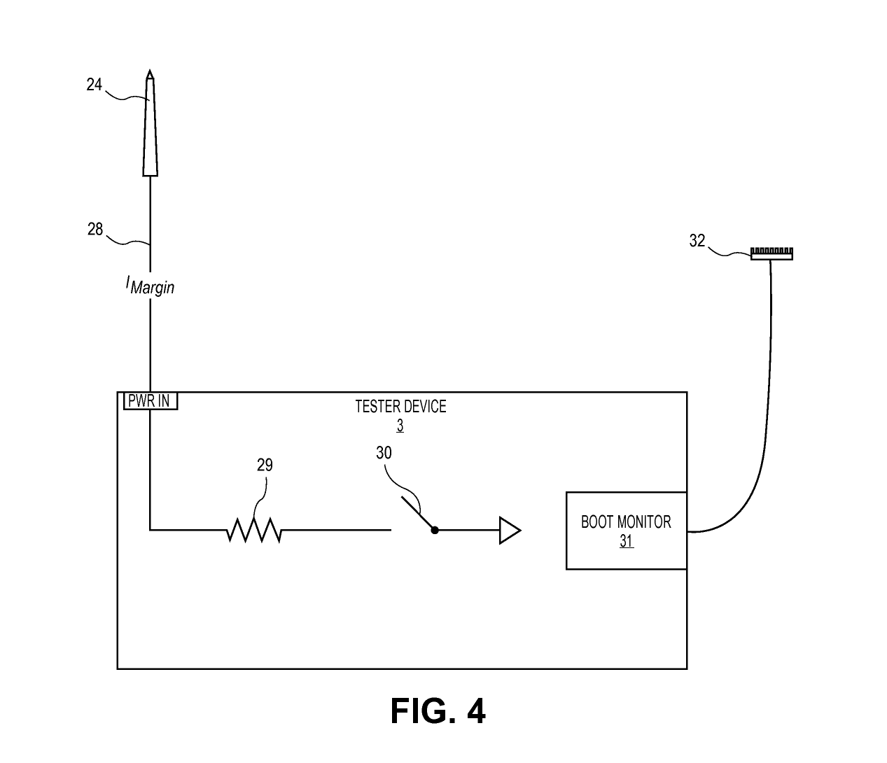

After the contact test probe 24 has been coupled to the test point 23 of the DUT 1 during a testing procedure, the tester device 3 steals the margin current I_{margin} from the boot current I_{boot}. The tester device 3 may steal the margin current I_{margin} using any type of current source 29. As shown in FIG. 4, the tester device 3 includes a resistor that acts as the current source 29 to draw the margin current I_{margin} through the contact test probe 24. The tester device 3 may also include a switch 30 for toggling the current source 29 on and off. The switch 30 may be manually activated by a user upon commencement of a test procedure and before booting of the DUT 1 begins. In another embodiment, the switch 30 is automatically activated upon the input current Iᵢₙ being delivered to the DUT 1. In this embodiment, the tester device 3 is also the external power source 17.

In one embodiment, the tester device 3 includes a boot monitor 31 for detecting whether the DUT 1 performed a successful boot using the diminished boot current. The boot monitor 31 may include a data input connector 32 (e.g. a multi-pin docking connector) for coupling to a test communications interface 33 of the DUT 1 and for receiving data signals from the DUT 1. The data signals may include an indication that the DUT 1 has successfully booted using the diminished boot current. For example, the data signals may indicate that using the diminished boot current the DUT 1 has successfully enumerated with a host device (e.g., the external power source 17 or the tester device 3), the processor 13 has successfully performed POR or POST operations, or the processor 13 has successfully found, loaded, and started an operating system. In another embodiment, the processor 13 may itself determine it has successfully booted using the diminished boot current and report the results to the tester device 3 or directly to a test engineer.

In one embodiment, the external power interface 18 and the test communications interface 33 are the same interface. In this embodiment, the data input connector 32 of the tester device 3 provides both the input current Iᵢₙ to the PMU 16 and allows data signals to be transmitted to the boot monitor 31. In one embodiment, the data signals indicate the current level used to successfully perform boot operations.

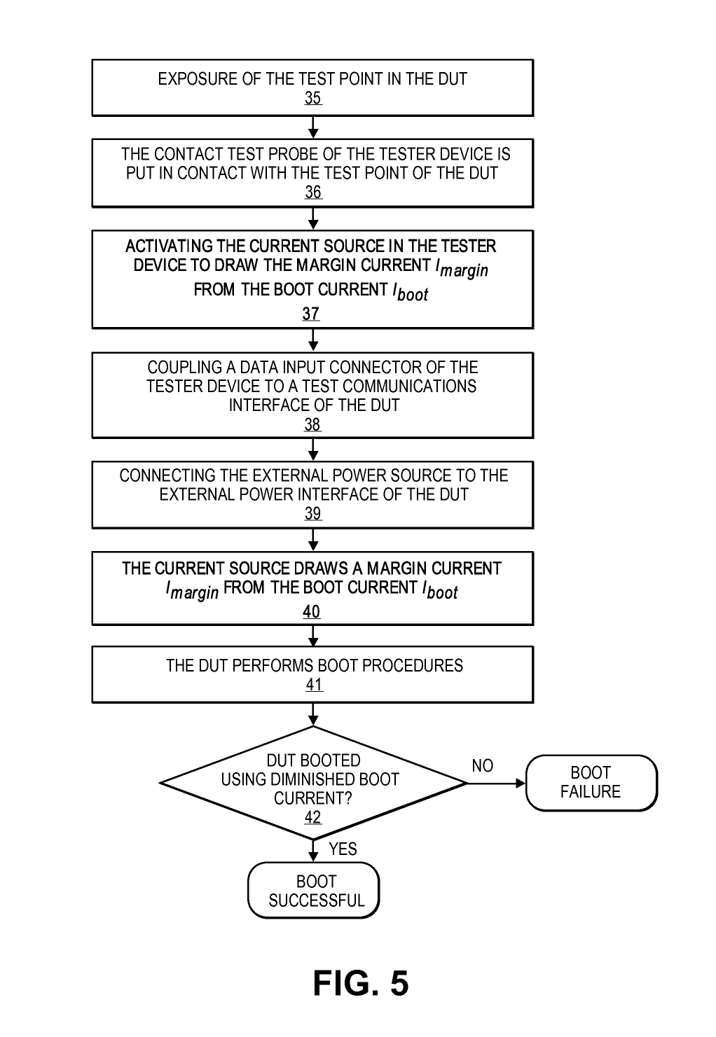

FIG. 5 shows a method for testing the tolerance of a processor 34 according to one embodiment. Each operation of the method 34 described below may be performed by one or more components of the boot cycle test system 2. The operations of the method 34 are not necessarily performed in the order described below or shown in FIG. 5.

The method for testing the tolerance of a processor 34 begins at operation 35 with the exposure of the test point 23 in the DUT 1. Exposing the test point 23 may include removal of a housing of the DUT 1. As described above, the DUT 1 may have one or more test points 23 located on circuit traces between components of the DUT 1. For example, the test point 23 may be located on a circuit trace between the display driver circuitry 25 and the touch display panel 4 of the DUT 1.

At operation 36, the contact test probe 24 of the tester device 3 is coupled to or placed in contact with the test point 23. In one embodiment, the contact test probe 24 is coupled to the test point 23 with a clip integrated into the tip of the probe 24. The contact between the probe 24 and the test point 23 creates an electrical pathway/ connection between the test point 23 and the current source 29 in the tester device 3.

At operation 37, the current source 29 in the tester device 3 is activated, turned on, or otherwise enabled. In one embodiment, activation of the current source 29 may be performed by a test engineer manually closing the switch 30 in the tester device 3. Activation of the current source 29 allows the margin current I_{margin} to be stolen from the current I_{boot} when the DUT 1 is powered to begin boot procedures.

At operation 38, the data input connector 32 is coupled to the test communications interface 33. The data input connector 32 allows data signals to pass from the DUT 1 to the boot monitor 31 of the tester device 3. Upon a successful boot by the processor 13 of the DUT 1, the boot monitor 31 receives data signals from the DUT 1 via the data input connector 32 indicating a successful boot.

At operation 39, the external power source 17 is connected to the external power interface 18 of the DUT 1. The DUT 1 draws an input current Iᵢₙ from the external power source 17. The input current Iᵢₙ is limited by the current limiter 19. In one embodiment, the external power source 17 is the tester device 3. In this embodiment, the test communications interface 33 is the same as the external power interface 18.

At operation 40, the current source 29 draws a margin current I_{margin} from the boot current I_{boot}. The drawing of the margin current I_{margin} is performed prior to the processor 13 beginning boot procedures.

At operation 41, the processor 13 retrieves the boot code 15 from the memory 14 and performs boot procedures according to the boot code 15. The boot procedures may include performing POR operations, POST operations, operations for finding, loading and starting an operating system, and operations for enumerating the DUT 1 with a host device (e.g., the tester device 3).

At operation 42, the boot monitor 31 detects whether the processor 13 successfully booted using the diminished boot current. In one embodiment, the boot monitor 31 detects that the processor 13 successfully booted using the diminished boot current after receipt of data signals from the DUT 1 indicating success. For example, the data signals may indicate that using the diminished boot current the DUT 1 has successfully enumerated with a host device (e.g., the external power source 17 or the tester device 3), the processor 13 has successfully performed POR or POST operations, or the processor 13 has successfully found, loaded, and started an operating system. Conversely, the boot monitor 31 may detect that the processor 13 failed to boot using the diminished boot current after not receiving data signals indicating success after a predetermined timeout period. For example, after not receiving a data signal indicating success after a timeout period of 20 seconds, the boot monitor 31 determines that the processor 13 did not successfully boot using the diminished boot current.

By performing the method for testing the tolerance of a processor 34 using the boot cycle test system 2 described above, the current level tolerances of the processor 13 integrated in the DUT 1 may be efficiently tested. In particular, the margin current I_{margin} may be drawn from the boot current I_{boot} to determine whether the processor 13 will boot using a current level that is lower than a current level typically restricted by a current limiter 19. If the DUT 1 is able to boot using the diminished boot current that is lower than the current level restricted by the current limiter 19, the DUT 1 is likely to boot under normal conditions using the current level restricted by only the current limiter 19. By drawing the margin current I_{margin}, a current limit value in the current limiter 19 does not need to be repeatedly rewritten for each DUT 1. This lack of adjustment of the current limit also prevents a costly boot cycle that would need to be performed after adjustment of the current limit and before testing the DUT 1 with the adjusted low current limit.

As explained above, an embodiment of the invention may be a machine-readable medium (such as microelectronic memory) having stored thereon instructions, which program one or more data processing components (generically referred to here as a “processor”) to perform operations for testing the tolerance of a processor in a mobile multi-function communications device under test as described above. In other embodiments, some of these operations might be performed by specific hardware components that contain hardwired logic (e.g., dedicated state machines). Those operations might alternatively be performed by any combination of programmed data processing components and fixed hardwired circuit components.

While certain embodiments have been described and shown in the accompanying drawings, it is to be understood that such embodiments are merely illustrative of and not restrictive on the broad invention, and that the invention is not limited to the specific constructions and arrangements shown and described, since various other modifications may occur to those of ordinary skill in the art. The description is thus to be regarded as illustrative instead of limiting.

What is claimed is:

1. A startup boot cycle test system for testing a mobile multi-function device under test (DUT) that has a power manager and a main system processor, comprising:
an external power source to provide an input current to the power manager of the mobile multi-function DUT, wherein the power manager is to then provide a boot current, drawn from the input current, to the main system processor; and
a tester device to cause a margin current to be drawn from the power manager so as to diminish the boot current that is being provided to the main system processor, the tester device to then determine if the main system processor successfully boots using the diminished boot current.

2. The startup boot cycle test system of claim 1, wherein the tester device further comprises a contact test probe that is to contact a test point of the mobile multi-function DUT, and through which the margin current is drawn into the tester device.

3. The startup boot cycle test system of claim 2, wherein the tester device includes:
a current source coupled to the contact test probe and preset to draw the margin current.

4. The startup boot cycle test system of claim 2, wherein the contact test probe is positioned to contact the test point in the mobile multi-function DUT, wherein the test point is on a power supply circuit trace that connects the power manager to a power supply input of display driver circuitry in the mobile multi-function DUT.

5. The startup boot cycle test system of claim 2, wherein the contact test probe is positioned to contact the test point in the mobile multi-function DUT, wherein the test point is on a power supply circuit trace that connects display driver circuitry to a display panel in the mobile multi-function DUT.

6. The startup boot cycle test system of claim 1, wherein the tester device further comprises a data input connector for communicating with the mobile device to receive a control signal indicating the main system processor has successfully booted.

7. The startup boot cycle test system of claim 1, wherein the external power source is a Universal Serial Bus (USB) host.

8. The startup boot cycle test system of claim 7, wherein the main system processor successfully boots upon enumerating with the host.

9. A method for testing a processor in a mobile device under test (DUT), comprising:
providing, by an external power source, an input current to a power manager of the mobile DUT;
providing, by the power manager, a boot current, drawn from the input current, to the processor;
drawing, by a tester device, a margin current from the power manager so as to diminish the boot current provided to the processor; and
detecting, by the tester device, whether the processor successfully booted using the diminished boot current.

10. The method of claim 9, further comprising:
coupling a contact test probe of the tester device to a test point of the mobile DUT to create a path through which the margin current is drawn.

11. The method of claim 10, wherein the tester device includes a current source coupled to the contact test probe and preset to draw the margin current.

12. The method of claim 10, wherein the contact test probe is positioned to contact the test point in the mobile DUT, wherein the test point is on a power supply circuit trace that connects the power manager to a power supply input of display driver circuitry in the mobile DUT.

13. The method of claim 10, wherein the contact test probe is positioned to contact the test point in the mobile DUT, wherein the test point is on a power supply circuit trace that connects display driver circuitry to a display panel in the mobile DUT.

14. The method of claim 9, further comprising:
coupling a data line from the tester device to the mobile DUT; and
receiving, by the tester device, a data signal over the data line when the processor successfully boots.

15. The method of claim 14, wherein the processor successfully boots upon enumerating with an external host.

16. The method of claim 15, wherein the external host is a Universal Serial Bus (USB) host and provides power to the mobile DUT.

17. A tester device for testing a mobile device, comprising:
a test probe for coupling to a test point of the mobile device;
a current source for sinking current from a system processor of the mobile device through the test point; and
a boot monitor for detecting a successful boot by the system processor.

18. The tester device of claim 17, further comprising:
a switch, which may be toggled by a user, for selectively activating the current source.

19. The tester device of claim 17, wherein the boot monitor includes a data input connector for communicating with the mobile device to receive control signals indicating the system processor has successfully booted.

20. The tester device of claim 19, wherein the system processor successfully boots upon enumerating with a host.

21. The tester device of claim 20, wherein the tester device is the host.
